(19) United States
(12) Patent Application Publication
(10) Pub. No.: US 2004/0203256 A1
(43) Pub. Date: Oct. 14, 2004

(54) Irradiation-assisted immobilization and patterning of nanostructured materials on substrates for device fabrication

(75) Inventors: Xiaomin Yang, Sewickley, PA (US); Chao Liu, Pittsburgh, PA (US); Earl Chrzaszcz Johns, Sewickley, PA (US); Paul Max Jones, Pittsburgh, PA (US)

Correspondence Address: Robert P. Lenart, Pietragallo, Bosick & Gordon, One Oxford Centre, 38th Floor, 301 Grant Street, Pittsburgh, PA, 15219, US

(73) Assignee: Seagate Technology LLC, Scotts Valley, CA

(21) Appl. No.: 10/409,217

(22) Filed: Apr. 8, 2003

(51) Int. Cl. H01L 21/31

(52) U.S. Cl. 438/780

(57) ABSTRACT

A method of fabricating a device comprising: depositing a self-assembled monolayer on a substrate; depositing a layer of surfactant coated nanostructured materials onto the self-assembled monolayer; and irradiating the layer of surfactant coated nanostructured materials and the self-assembled monolayer to bond nanostructured materials in the layer of surfactant coated nanostructured materials to the self-assembled monolayer. The method can be used to produce immobilized layers and/or patterned layers of nanostructured materials. Devices fabricated according to the method are also included.

### FIELD OF THE INVENTION

This invention relates to methods of fabricating nanostructured devices and to devices fabricated using those methods.

### BACKGROUND OF THE INVENTION

There have been intense efforts in the design and fabrication of structures on the nanometer scale. These structures must have specific properties, in the areas of optics, electronics, mechanics, magnetism and so forth.

Nanostructured materials differ from corresponding bulk materials and single atoms. Colloidal nanoparticles demonstrate great potential as the building blocks for ordered and complex materials. The fabrication of nanostructured materials onto substrates for application in devices, however, remains as a major challenge.

Many practical applications of devices in photo-electronic, electronic, sensor, storage and display technologies require the two- or three-dimensional patterning of nanostructured materials (in one layer or several layer thin films) on surfaces. One of the challenges is how to immobilize nanostructured materials on a substrate after the patterning process. For example, after patterning of magnetic nanoparticles on a disc for patterned magnetic storage media, nanoparticles are required to be strongly attached on the disc surface through other processing steps, such as washing, annealing, and so on.

There is a need for a method of fabricating devices using the patterned nanostructured materials that are strongly attached to a surface with long range ordering.

### SUMMARY OF THE INVENTION

This invention provides a method of fabricating a device comprising: depositing a self-assembled monolayer on a substrate; depositing a layer of surfactant coated nanostructured materials onto the self-assembled monolayer; and irradiating the layer of surfactant coated nanostructured materials and the self-assembled monolayer to bond nanostructured materials in the layer of surfactant coated nanostructured materials to the self-assembled monolayer.

The irradiating step can be applied to portions of the layer of surfactant coated nanostructured materials and the self-assembled monolayer, with non-irradiated portions being subsequently removed to form a patterned device.

The self-assembled monolayer can comprise a plurality of molecules, each of the molecules including a surface-active head group, a terminal group and an intermediate portion between the surface-active head group and the terminal group. The surfactant coated nanostructured materials can include nanostructured materials comprising, for example, nanoparticles, nanotubes, nanowires, nanobelts or nanodisks.

In another aspect, the invention encompasses devices comprising a self-assembled monolayer on a substrate, and a layer of surfactant coated nanostructured materials on the self-assembled monolayer, wherein the surfactant coated nanostructured materials and the self-assembled monolayer are covalently bonded to each other.

### BRIEF DESCRIPTION OF THE DRAWINGS

FIG. 1 is a schematic representation of several intermediate structures that can be formed when practicing the method of the invention.

FIG. 2 is a schematic representation of a self-assembled monolayer (SAM) on a surface.

FIG. 3 is a schematic representation of the formation of a SAM on a substrate.

FIG. 4a is a schematic representation of a nanoparticle surrounded by surfactants.

FIGS. 4b and 4c are schematic representations of surfactants.

FIG. 5 schematically illustrates cross-linking in the SAM layer and nanoparticle layer.

FIG. 6 schematically illustrates the fabrication of one or more multilayers of nanoparticles into a solid surface device.

### DETAILED DESCRIPTION OF THE INVENTION

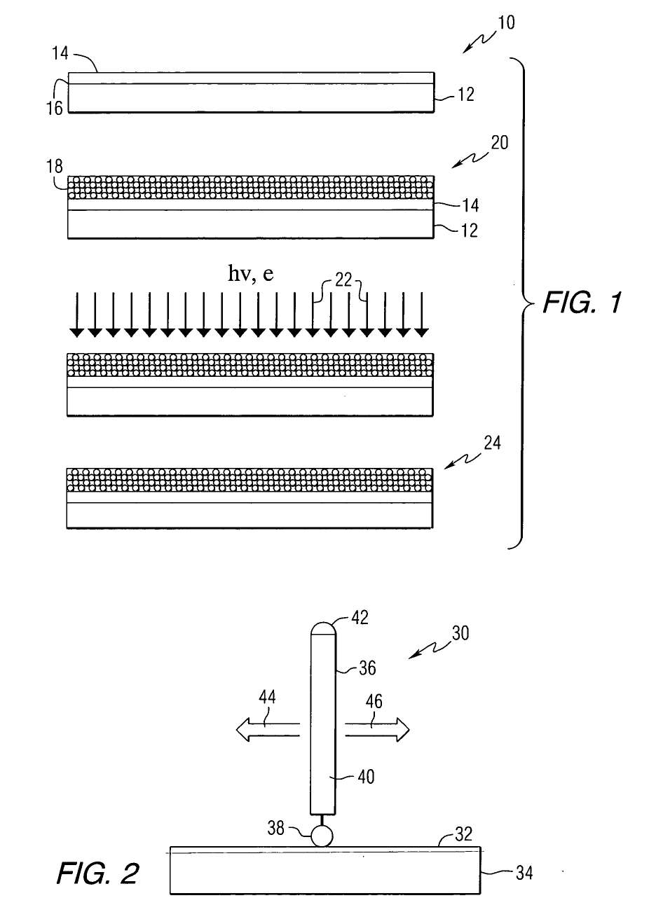

Referring to the drawings, FIG. 1 illustrates a method of irradiation-assisted immobilization of nanostructured materials on a solid substrate for device fabrication in accordance with the invention. Structure 10 is a portion of a substrate 12 having an undercoating layer 14, also called an imaging layer, deposited on a surface 16 of the substrate. A layer of nanostructured materials 18, also called a feature layer, is deposited on the undercoating layer 14 to form structure 20. Structure 20 is then subjected to photon or electron radiation as illustrated by arrows 22. The radiation causes the nanostructured materials layer to chemically bond to itself and to the underlayer to produce structure 24.

The process illustrated in FIG. 1 includes: deposition of an undercoating layer material onto a substrate; deposition of a layer of nanostructured materials onto the undercoating layer, and irradiation of the sample to bond the nanostructured materials layer to the undercoating layer. In the example of FIG. 1, the nanostructured materials are nanoparticles. A radiation source can provide, for example, ultraviolet (UV) radiation, deep UV radiation, extreme UV (EUV) radiation, an e-beam, an X-ray, an ion beam, low energy electrons from a scanning tunneling microscope (STM) or the electric field from a conducting atomic force microscopy (AFM) tip. During irradiation, both the undercoating layer material and the layer of nanostructured materials undergo a radical chemical reaction so that the undercoating layer material strongly bonds to the nanostructured material layer via chemical covalent bonds. Therefore, the nanostructured materials will be immobilized on the surface of the substrate after the irradiation process, and will not be removed during subsequent processing, such as washing and/or drying etc.

A wide variety of substrates can be used, including substrates typically used today in device fabrication, such as silicon, aluminum, glass, coinage metals (Au, Ag, Cu) etc. In this invention, a self-assembled monolayer (SAM) is used as the undercoating layer. The nanostructured materials layer can be comprised of nanoparticles, nanottibes, nanowires, nanobelts, nanodisks, etc.

A self-assembled monolayer (SAM) is used to chemically modify the surface properties of the substrate. FIG. 2 shows a schematic representation of a portion of a self-assembled monolayer (SAM) 30 on surface 32 of a silicon substrate 34. From the energetics point of view, a SAM molecule 36 can be divided into three parts. The first part 38 is the surface-active head group, which is chemically adsorbed on the surface of a substrate. The adsorption can be in the form of covalent Si—O bonds in the case of alkyltrichlorosilanes on hydroxylated surfaces. The second molecular part 40 can be an alkyl chain or aromatic group. The third molecular part 42 is the terminal functionality, which can be various functional groups, such as —CH₃, —COOH, —CHO, —OH, and so on. The molecules are subjected to energies associated with interchain van der Waals interactions as schematically represented by arrows 44 and 46.

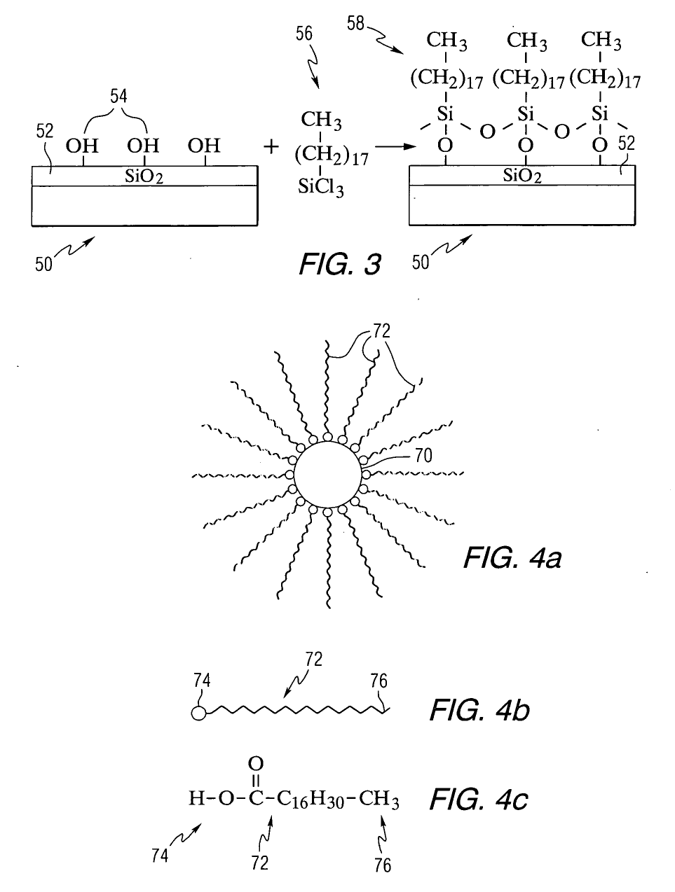

FIG. 3 is a schematic representation of the formation of a SAM on a substrate, which is silicon in this example. First the substrate 50 is cleaned, using for example piranha solution, leaving a SiO₂ layer 52 and a plurality of hydroxyl (—OH) groups 54. Molecules of material used to form the self-assembled layer, such as octadecyltrichlorosilane (OTS), 56 are introduced to produce an array 58 of self-assembled molecules on the Sio₂ layer of the substrate.

More specifically, to perform the process illustrated in FIG. 3, a silicon wafer can be first placed in a glass dish and covered with piranha solution (H₂SO₄:H₂0₂=70:30 (v/v)) at room temperature for 30 minutes. The mixture can be heated for an additional 30 minutes at 90° C. and then cooled to room temperature. Next, the substrate is immediately rinsed with deionized water several times and blown dry with nitrogen. The piranha solution leaves the substrate with a layer of relatively high-density hydroxyl (OH) groups.

Next, the substrate, which now has an outer surface with a film of hydroxyl groups, is immersed for a few minutes in an alkylsiloxane, which can be a dilute solution of, for example, an octadecyltrichlorosilane (OTS) ligand. Alternatively, self-assembled films can also be deposited from the vapor phase or with spin coating techniques. The alkylsiloxanes chemically bond to the hydroxyl groups to form an undercoating layer that is a monolayer, which is shown in FIG. 2. The monolayer includes a plurality of terminal groups, such as methyl (CH₃) groups, which are assembled onto the cleaned surface of the substrate.

Surfactant coated monodispersed nanoparticles can be used as the nanostructured layer materials. FIG. 4a is a schematic representation of a nanoparticle 70 surrounded by surfactants 72. FIGS. 4b and 4c are schematic representations of surfactants 72. FIG. 4b shows that the surfactants 72 include a hydrophilic portion 74 and a hydrophobic portion 76. FIG. 4c is a chemical formula of an example surfactant 72. The nanoparticles can include, but are not limited to: CdSe, CdS, PbS, GaAs, Si, TiO₂, ZnO, SnO₂, FePt, CoPt, FePd, Co, CoFe₂O_{4 and BaFe}₁₂O₁₉ nanoparticles. The surfactant molecules around the particles can include, but not limited to: oleic acid, oleylamine, trioctylphosphine oxide (TOPO), hexanoic acid, dodelcyl benzene sodium sulfate and sodium dodecylsulfonate. Generally speaking, the hydrophilic part of the surfactant molecule will attach to the particle surface.

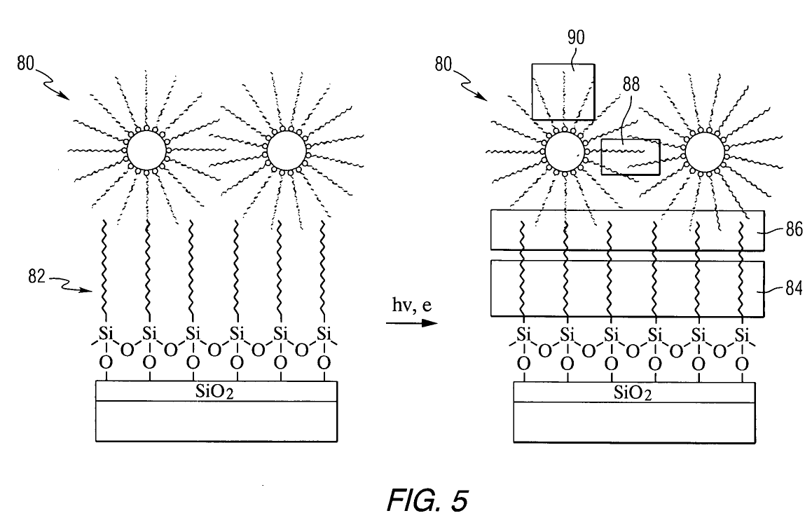

A layer 80 of nanoparticles would be deposited on the array 82 of self-assembled molecules as illustrated in FIG. 5. When the structure is subsequently subjected to radiation, cross-linking occurs both between the SAM layer and nanoparticle layer and within each of the layers. Item numbers 84, 86, 88 and 90 illustrate various areas of cross-linking. The cross-linking can be in the form of covalent bonds.

There are several advantages of using SAMs. SAMs are highly ordered molecular assemblies on a substrate driven by thermodynamics to form extremely high coverage films. The self-assembly mechanism is automatically defect rejecting and self-registering on a scale of molecular dimensions. SAMs can provide a pure chemically homogenous surface with a monolayer thickness of 1-2 nm. The surface chemistry properties of the SAM array are easily controlled by selecting terminal functional groups of SAMs that meet the needs of the nanoparticle assembly. In addition, SAMs can be strongly chemically bonded to the substrate.

In one example of the invention, the self-assembled layer can comprise molecules of RSiCl₃ (where R can be an alkyl or aromatic group with terminal functional groups). The terminal functional groups can be, for example, —CH₃, —COOH, —CHO or —OH. These groups are used in SAMs because they can form on technologically relevant substrates such as a native oxide layer of silicon, oxidized metal or polymeric planarizing layers. SAMs of alkylsiloxanes have a high degree of stability due to Si—O-substrate covalent linkage. They are thermally stable under vacuum up to temperatures of 740° K., and they can be molecularly engineered to be highly sensitive to various types of radiation, including electron beam, deep UV, or X-ray, ion beam or EUV. In addition to SAMs alkylsiloxanes, other SAMs such as alkylthiols can also be used in this invention.

Monodispersed nanoparticles can be deposited onto the undercoating layer by various techniques that may include dip coating, spin coating, drop coating, Langmuir-Blodgett film, etc. Selection of the best approach will be determined by the feasibility of achieving a feature layer with good control of the uniformity over the large-scale coating, which may vary depending upon the use of different nanostructured materials. The capability to obtain monolayers as well as multilayers should also be considered during the optimization of the coating techniques.

During irradiation, cross-linking will occur with the following constituents of the structure: (a) among the SAM molecules 84; (b) between surfactant molecules around the particles and the SAM 86; (c) between the surfactant molecules around different particles 88; and (d) among the surfactant molecules around individual particles 90. This causes the particles to be registered to the substrate and immobilizes the neighboring particles so that they will not be removed during various subsequent processes such as washing, drying, annealing, and so forth.

In one example of the invention, self-assembled films of octadecyltrichlorosilane (OTS) are used as undercoating layer materials which are chemically bonded on Si/SiO₂ substrate. The OTS is chemically bonded to the hydroxylated surfaces to form an undercoating layer on Si/SiO₂ substrate. The nanoparticles are surrounded with surfactant molecules and deposited as the nanostructured layer materials. Deep-UV or e-beam radiation is used to bond the materials to each other.

The exposure process can be accomplished by an electron beam, or deep UV in this example. The major effect of ionizing radiation is the loss of hydrogen via cleavage of CH bonds. The mechanism of the ionizing beam radiation in hydrocarbon molecules can be described in terms of the radiation impact and radical reactions for hydrocarbon irradiation which are summarized in equations 1-5.

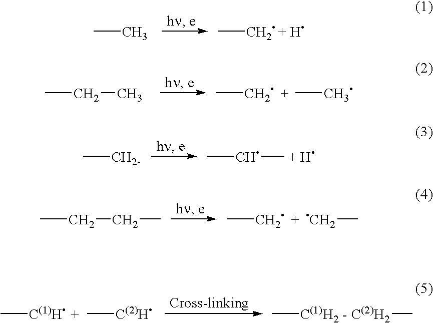

With the initial formation of the free radicals due to the bond dissociation in a number of processes, as indicated in equations 1-4, which involve primary and secondary electrons emitted from the substrate, termination will take place when two radicals react with each other, as shown in equation 5. The free radicals from the SAM recombine with other radicals from neighboring groups of the surfactant molecules around the particles to form cross-links.

Although the production of radicals may be most probable at the surface, free radicals are produced throughout the thickness of the imaging layer as well as the feature layer of the self-assembled surfactant coated nanoparticles. It is likely that not only free radicals in the interior of the chains react to form cross-links, but also radical intermediates from neighboring groups undergo the combination process. Therefore strong covalent C—C bonds are found between the SAM molecules and the surfactant coated particles, and among the surfactant coated particles. Cross-linking is found: (a) among the SAM molecules, (b) between surfactant molecules around the particles and SAM molecules, (c) between the surfactant molecules around different particles, and (d) among the surfactant molecules around one particle, as shown in FIG. 5. After irradiation of the assembled monolayer or multilayer particles, the washing process can only remove the particles at the unexposed region.

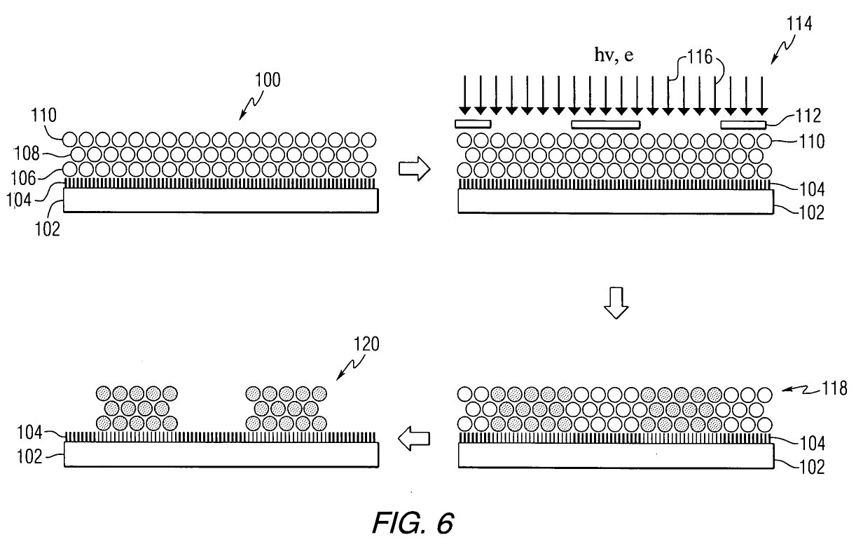

FIG. 6 shows an example about how to fabricate a monolayer or multilayers of nanoparticles into a solid surface for device fabrication. Structure 100 includes a substrate 102 with a SAM 104 on a surface of the substrate. A plurality of particle layers 106, 108 and 110 are deposited on the SAM. A mask 112 is applied on top of layer 110 to obtain structure 114. That structure is then subjected to radiation as illustrated by arrows 116. The mask can then be removed using known processes to form structure 118 in which the portions of the particle layers and the SAM that were exposed to the radiation have been bonded to each other. Structure 118 is then washed to remove the unbonded portions of the particle layer and the SAM and the structure is dried to produce the patterned structure 120. In addition to using a mask to shield portions of the layers, it will be apparent that other techniques can be employed to irradiate some portions of the layers while leaving other portions unexosed to the radiation, for example, electron beam direct writing.

The invention has been demonstrated to form nanoparticles on a SAM-modified surface using e-beam irradiation (50 keV) after washing with appropriate solvent such as Hexane and Octane, and a SAM-modified surface using deep UV irradiation through a TEM grid as mask for 10 min. at 10 mW/cm², and then washing with hexane (or octane). The particles at the unexposed regions were washed away. However, the particles at the exposed region are strongly attached to the surface. A clear border line was formed between the two different areas. Inside the exposed area, the particles were self-organized into the superlattice as verified by the high resolution scanning electron microscopy (HRSEM) imaging. The assembly was not destroyed by the irradiation and the washing process. There were no particles found at the unexposed area after washing process by using Hexane and Octane.

The invention provides a method of immobilizing and patterning nanostructured materials on surfaces by an irradiation-assisted photochemical reaction between nanostructured materials and substrate. The patterned nanostructured materials with long range ordering can be achieved by separately optimizing the deposition of the nanostructured materials and the irradiation steps. The method of this invention is relatively simple and can be readily produced in a mass production environment. This method can be used for a variety of device fabrication applications whenever nanostructured materials need to be immobilized on surfaces.

The invention also encompasses nanostructured devices comprising a self-assembled monolayer on a substrate, and a layer of surfactant coated nanostructured materials on the self-assembled monolayer, wherein the surfactant coated nanostructured materials and the self-assembled monolayer are covalently bonded to each other.

The self-assembled monolayer can comprise a plurality of molecules, each of the molecules including a surface-active head group, a terminal group and an intermediate portion between the surface-active head group and the terminal group. The surface-active head group can comprise —SiCl₃. The intermediate portion can comprise an alkyl or aromatic group. The terminal group can comprise one of: —CH₃, —COOH, —CHO, and —OH.

The self-assembled monolayer can comprise an alkylsiloxane or an alkylthiol. The surfactant coated nanostructured materials can include a surfactant comprising one of: oleic acid, oleylamine, trioctylphosphine oxide (TOPO), hexanoic acid, dodelcyl benzene sodium sulfate and sodium dodecylsulfonate. The surfactant coated nanostructured materials can include nanostructured materials comprising one of: CdSe, CdS, PbS, GaAs, Si, TiO₂, ZnO, SnO₂, FePt, CoPt, FePd, Co, CoFe₂O₄ and BaFe₁₂O₁₉ nanoparticles.

While the invention has been described in terms of several examples, it will be apparent to those skilled in the art that various changes can be made to the disclosed examples without departing from the scope of the invention as defined by the following claims.

What is claimed is:

1. A method of fabricating a device comprising:
depositing a self-assembled monolayer on a substrate;
depositing a layer of surfactant coated nanostructured materials onto the self-assembled monolayer; and
irradiating the layer of surfactant coated nanostructured materials and the self-assembled monolayer to bond nanostructured materials in the layer of surfactant coated nanostructured materials to the self-assembled monolayer.

2. The method of claim 1, wherein the self-assembled monolayer comprises:
a plurality of molecules, each of the molecules including a surface-active head group, a terminal group and an intermediate portion between the surface-active head group and the terminal group.

3. The method of claim 2, wherein the surface-active head group comprises: —SiCl₃.

4. The method of claim 2, wherein the intermediate portion comprises:
an alkyl or aromatic group.

5. The method of claim 2, wherein the terminal group comprises one of: —CH₃, —COOH, —CHO, and —OH.

6. The method of claim 1, wherein the self-assembled monolayer comprises an alkylsiloxane or an alkylthiol.

7. The method of claim 1, wherein the surfactant coated nanostructured materials include a surfactant that comprises one of: oleic acid, oleylamine, trioctylphosphine oxide (TOPO), hexanoic acid, dodelcyl-benzene sodium sulfate and sodium dodecylsulfonate.

8. The method of claim 1, wherein the surfactant coated nanostructured materials includes nanostructured materials comprising one of: CdSe, CdS, PbS, GaAs, Si, TiO₂, ZnO, SnO₂, FePt, CoPt, FePd, Co, CoFe₂O₄ and BaFe₁₂O₁₉ nanoparticles.

9. The method of claim 1, wherein the surfactant coated nanostructured materials include nanostructured materials comprising one of: nanoparticles, nanotubes, nanowires, nanobelts and nanodisks.

10. The method of claim 1, wherein the step of irradiating the layer of surfactant coated nanostructured materials and the self-assembled monolayer comprises irradiating the layer of surfactant coated nanostructured materials and the self-assembled monolayer using one of: electron beam radiation, deep ultraviolet radiation, X-ray radiation, ion beam radiation, extreme ultraviolet radiation, low energy electrons from a scanning tunneling microscope or an electric field from a conducting atomic force microscopy tip.

11. The method of claim 1, wherein portions of the layer of surfactant coated nanostructured materials and the self-assembled monolayer are not irradiated, and the portions of the layer of surfactant coated nanostructured materials and the self-assembled monolayer that are not irradiated are subsequently removed.

12. A device fabricated according to the method of claim 1.

13. A device comprising:
a self-assembled monolayer on a substrate;
a layer of surfactant coated nanostructured materials on the self-assembled monolayer; and
wherein the surfactant coated nanostructured materials and the self-assembled monolayer are covalently bonded to each other.

14. The device of claim 13, wherein the self-assembled monolayer comprises:
a plurality of molecules, each of the molecules including a surface-active head group, a terminal group and an intermediate portion between the surface-active head group and the terminal group.

15. The device of claim 14, wherein the surface-active head group comprises: —SiCl₃.

16. The device of claim 14, wherein the intermediate portion comprises:
an alkyl or aromatic group.

17. The device of claim 14, wherein the terminal group comprises one of: —CH₃, —COOH, —CHO, and —OH.

18. The device of claim 13, wherein the self-assembled monolayer comprises an alkylsiloxane or an alkylthiol.

19. The device of claim 13, wherein the surfactant coated nanostructured materials include a surfactant comprising one of: oleic acid, oleylamine, trioctylphosphine oxide (TOPO), hexanoic acid, dodelcyl-benzene sodium sulfate and sodium dodecylsulfonate.

20. The device of claim 13, wherein the surfactant coated nanostructured materials include nanostructured materials comprising one of: CdSe, CdS, PbS, GaAs, Si, TiO₂, ZnO, SnO₂, FePt, CoPt, FePd, Co, CoFe₂O_{4 and BaFe}₁₂O₁₉ nanoparticles.

21. The device of claim 13, wherein the surfactant coated nanostructured materials include nanostructured materials comprising one of: nanoparticles, nanotubes, nanowires, nanobelts and nanodisks.
